(19) United States
(12) Patent Application Publication
(10) Pub. No.: US 2019/0249080 A1
(43) Pub. Date: Aug. 15, 2019

(54) RED FLUORESCENT SUBSTANCE, METHOD FOR PRODUCING RED FLUORESCENT SUBSTANCE, WHITE LIGHT SOURCE, LIGHTING DEVICE, AND LIQUID CRYSTAL DISPLAY DEVICE

(71) Applicant: DEXERIALS CORPORATION, Tokyo (JP)

(72) Inventors: Moriaki ABE, Tokyo (JP); Masaki KANNO, Tokyo (JP)

(73) Assignee: DEXERIALS CORPORATION, Tokyo (JP)

(21) Appl. No.: 16/271,011

(22) Filed: Feb. 8, 2019

(30) Foreign Application Priority Data
Feb. 13, 2018 (JP) 2018-022879

(51) Int. Cl. C09K 11/77; H01L 33/50; H01L 27/15; G02F 1/1335

(52) U.S. Cl. CPC C09K 11/7734; H01L 33/504; G02F 2001/133614; G02F 1/133621; H01L 2933/0041; H01L 27/156

(57) ABSTRACT

A red fluorescent substance including: element A, europium (Eu), silicon (Si), aluminum (Al), oxygen (O), and nitrogen (N) at ratios of numbers of atoms in Compositional Formula (1) below.

[A₍ₘ₋ₓ₎Euₓ]Si₉Al_{y}OₙN_{[12+y-2(n-m)/3]} Compositional Formula (1)

In the Compositional Formula (1), the element A is a Group 2 element including calcium (Ca) and barium (Ba), m, x, y, and n in the Compositional Formula (1) satisfy 3<m<5, 0<x<1, 0.012≤y≤0.10, and 0<n<10, respectively and when a ratio of the number of Ca atoms is α and a ratio of the number of Ba atoms is β, the Compositional Formula (I) satisfies Formula (I) below:

0.05≤α/(α+β)<1.00 Formula (I).

### CROSS-REFERENCE TO RELATED APPLICATIONS

This application claims priority to Japanese application No. 2018-022879, filed on Feb. 13, 2018 and incorporated herein by reference.

### BACKGROUND OF THE INVENTION

### Field of the Invention

The present invention relates to a red fluorescent substance, a method for producing a red fluorescent substance, a white light source, a lighting device, and a liquid crystal display device.

### Description of the Related Art

A white light source composed of light emitting diodes is used for a backlight of a lighting device or a liquid crystal display device. As the above-described white light source, those in which a fluorescent substance is disposed at a side of the emitting surface of a blue light emitting diode (hereinafter referred to as a blue LED) are known. In such a white light source, a variety of fluorescent substances, which are excited by blue light from a blue LED and emit light of an arbitrary wavelength, are used in order to provide color tones depending on its application.

In the above-described white light source, white light has been conventionally produced using a yellow fluorescent substance. However, the white light produced becomes slightly bluish compared to natural light including light having a wide range of wavelengths. Therefore, it is considered that the light which is closer to the natural light is produced by mixing a red fluorescent substance emitting a long wavelength therewith, and the practical application is also being made. Especially, in recent years, the lighting improved in the color rendering property is actively developed, and the characteristics of the red fluorescent substance are an important element for improving the color rendering property.

Therefore, as a red fluorescent substance having a large emission intensity, a red fluorescent substance having the following Compositional Formula (1) has been proposed (see, for example, Japanese Patent (JP-B) No. 4730458).

[A₍ₘ₋ₓ₎Euₓ]Si₉Al_{y}OₙN_{[12+y-2(n-m)/3]} Compositional Formula (1)

Here, element A in the Compositional Formula (1) is at least one of magnesium (Mg), calcium (Ca), strontium (Sr), or barium (Ba), and m, x, y, and n in the Compositional Formula (1) satisfy the relationship of 3<m<5, 0<x<1, 0<y<2, and 0<n<10.

### SUMMARY OF THE INVENTION

When a red fluorescent substance is used in a white light source using a light emitting diode, it is desirable that emission intensity of a long wavelength of 700 nm or more contributing to the expansion of the color gamut be large and deterioration be hardly caused even in the use for a long time.

However, the technique described in Japanese Patent (JP-B) No. 4730458 is deteriorated in long-term use in some cases.

The present invention is proposed in light of such conventional circumstances, and relates to a red fluorescent substance, which has a large emission intensity of a long wavelength of 700 nm or more and is hardly deteriorated even in long-term use, to a method for producing the red fluorescent substance, and to a white light source, a lighting device, and a liquid crystal display device each using the red fluorescent substance.

Means for solving the above problems are as follows. That is,

<1> A red fluorescent substance including:

element A, europium (Eu), silicon (Si), aluminum (Al), oxygen (O), and nitrogen (N) at ratios of numbers of atoms in Compositional Formula (1) below:

[A₍ₘ₋ₓ₎Euₓ]Si₉Al_{y}OₙN_{[12+y-2(n-m)/3]} Compositional Formula (1)

where in the Compositional Formula (1), the element A is a Group 2 element including calcium (Ca) and barium (Ba), m, x, y, and n in the Compositional Formula (1) satisfy 3<m<5, 0<x<1, 0.012≤y≤0.10, and 0<n<10, respectively and when a ratio of the number of Ca atoms is α and a ratio of the number of Ba atoms is β, the Compositional Formula (I) satisfies Formula (I) below:

0.05≤α/(α+β)<1.00 Formula (I).

<2> The red fluorescent substance according to <1>,

wherein the Compositional Formula (1) further satisfies Formula (II) below:

0.30≤β/(α+β)<1.00 Formula (II).

<3> The red fluorescent substance according to <1> or <2>,

wherein the Compositional Formula (1) further satisfies Formula (III) below:

0.50≤(α+β)/(m−x)≤1.00 Formula (III).

<4> The red fluorescent substance according to any one of <1> to <3>, wherein when emission intensity of a maximum emission wavelength at an excitation wavelength of 450 nm in PLE (Photoluminescence Excitation) spectrum is 1, emission intensity at 720 nm is 0.2 or more.

<5> The red fluorescent substance according to any one of <1> to <4>,

wherein when emission intensity of a maximum emission wavelength at an excitation wavelength of 450 nm in PLE (Photoluminescence Excitation) spectrum is 1, emission intensity at 750 nm is 0.1 or more.

<6> A method for producing the red fluorescent substance according to any one of <1> to <5>, the method including:

mixing a compound of element A, a europium compound that is europium nitride, europium oxide, or both thereof, silicon nitride, aluminum nitride, and melamine to form a mixture so that the element A, europium (Eu), silicon (Si), aluminum (Al), oxygen (O), and nitrogen (N) have ratios of numbers of atoms in the Compositional Formula (1), and baking the mixture; and pulverizing a baked product obtained through the baking.

<7> The method for producing the red fluorescent substance according to <6>,

wherein the baking the mixture and the pulverizing the baked product obtained through the baking are repeatedly performed.

<8> A white light source including:

a blue light emitting diode formed on an element substrate; and

a kneaded product that is disposed on the blue light emitting diode and is obtained by kneading a red fluorescent substance and a green fluorescent substance in a transparent resin,

wherein the red fluorescent substance is the red fluorescent substance according to any one of <1> to <5>.

<9> A lighting device including:

a lighting substrate; and

a plurality of white light sources disposed on the lighting substrate,

wherein each of the plurality of white light sources is the white light source according to <8>.

<10> A liquid crystal display device including:

a liquid crystal panel; and

a backlight using a plurality of white light sources configured to light the liquid crystal panel,

wherein each of the plurality of white light sources is the white light source according to <8>.

According to the present invention, it is possible to provide a red fluorescent substance, which has a large emission intensity of a long wavelength of 700 nm or more and is hardly deteriorated even in long-term use, to provide a method for producing the red fluorescent substance, and to provide a white light source, a lighting device, and a liquid crystal display device each using the red fluorescent substance.

### BRIEF DESCRIPTION OF THE DRAWINGS

FIG. 1 is a flow chart illustrating one embodiment of a method of the present invention for producing a red fluorescent substance;

FIG. 2 is a schematic cross-sectional view illustrating one embodiment of a white light source of the present invention;

FIG. 3A is a schematic planar view illustrating one embodiment of a lighting device of the present invention;

FIG. 3B is a schematic planar view illustrating another embodiment of a lighting device of the present invention;

FIG. 4 is a schematic configuration diagram illustrating one embodiment of a liquid crystal display device of the present invention; and

FIG. 5 presents results of an LED continuous lighting test of samples 1 to 5 and 14.

### DESCRIPTION OF THE EMBODIMENTS

### (Red Fluorescent Substance)

A red fluorescent substance of the present invention includes element A, europium (Eu), silicon (Si), aluminum (Al), oxygen (O), and nitrogen (N) at ratios of numbers of atoms in Compositional Formula (1) below:

[A₍ₘ₋ₓ₎Euₓ]Si₉Al_{y}OₙN_{[12+y-2(n-m)/3]} Compositional Formula (1)

Here, in the Compositional Formula (1), the element A is a Group 2 element including calcium (Ca) and barium (Ba). m, x, y, and n in the Compositional Formula (1) satisfy 3<m<5, 0<x<1, 0.012≤y≤0.10, and 0<n<10, respectively. When a ratio of the number of Ca atoms is a and a ratio of the number of Ba atoms is f, the Compositional Formula (I) satisfies Formula (I) below:

0.05≤α/(α+β)<1.00 Formula (I).

Here, when a ratio of the number of atoms of the Group 2 element excluding Ca and Ba is γ, the following formula: m−x=α+β+γ is satisfied.

In a red fluorescent substance including element A, europium (Eu), silicon (Si), aluminum (Al), oxygen (O), and nitrogen (N) at ratios of numbers of atoms in Compositional Formula (1-1) below, the present inventors have found that it is possible to obtain such a red fluorescent substance that has a large emission intensity of a long wavelength of 700 nm or more and is hardly deteriorated even in long-term use, when the element A is a Group 2 element including calcium (Ca) and barium (Ba), a ratio between Ca and Ba satisfies Formula (I) below where a ratio of the number of Ca atoms is α and a ratio of the number of Ba atoms is β. As a result, the present inventors have completed the present invention.

0.05≤α/(α+β)<1.00 Formula (I).

[A₍ₘ₋ₓ₎Euₓ]Si₉Al_{y}OₙN_{[12+y-2(n-m)/3]} Compositional Formula (1-1)

Here, in the Compositional Formula (1-1), the element A is a Group 2 element. m, x, y, and n in the Compositional Formula (1-1) satisfy 3<m<5, 0<x<1, 0.012≤y≤0.10, and 0<n<10, respectively.

When the element A is only Ca, emission intensity of a long wavelength of 700 nm or more tends to increase. However, emission intensity of the maximum emission wavelength of about 650 nm decreases, further resulting in deterioration in long-term use.

When the element A is only Ba, deterioration hardly occurs in long-term use. However, the maximum emission wavelength shifts to a side of a short wavelength to thereby deteriorate emission intensity of a long wavelength, and emission intensity of the maximum emission wavelength is also deteriorated.

In addition, when the element A is only a combination of Ba and Sr, emission intensity of the maximum emission wavelength is relatively high, and deterioration in long-term use hardly occurs. However, the maximum emission wavelength shifts to a side of a short wavelength, resulting in a decrease in emission intensity of a long wavelength.

Examples of the Group 2 element in the Compositional Formula (1) include magnesium (Mg), calcium (Ca), strontium (Sr), and barium (Ba).

The element A is a Group 2 element including calcium (Ca) and barium (Ba) and may be a Group 2 element including calcium (Ca), strontium (Sr), and barium (Ba).

In the Compositional Formula (1), m satisfies 3<m<5, preferably satisfies 3.5<m<4.

In the Compositional Formula (1), x satisfies 0<x<1, preferably satisfies 0.1<x<0.3.

In the Compositional Formula (1), y satisfies 0.012≤y≤0.10, preferably satisfies 0.05<y<0.10.

In the Compositional Formula (1), n satisfies 0<n<10, preferably satisfies 0.5<n<2.

The Compositional Formula (1) satisfies the Formula (I). The Compositional Formula (1) preferably satisfies Formula (I-1) below, more preferably satisfies Formula (I-2) below, particularly preferably satisfies Formula (I-3) below, because the red fluorescent substance is less likely to deteriorate even in long-term use.

0.05≤α/(α+β)≤0.50 Formula (I-1)

0.05≤α/(α+β)≤0.40 Formula (I-2)

0.10≤α/(α+β)≤0.40 Formula (I-3)

The Compositional Formula (1) preferably satisfies Formula (II) below, more preferably satisfies Formula (II-1) below, still more preferably satisfies Formula (II-2) below, particularly preferably satisfies Formula (II-3) below, because the red fluorescent substance is less likely to deteriorate even in long-term use.

0.30≤β/(α+β)≤1.00 Formula (II)

0.50≤β/(β+β)≤1.00 Formula (II-1)

0.60≤β/(α+β)≤0.95 Formula (II-2)

0.60≤β/(α+β)≤0.90 Formula (II-3)

The Compositional Formula (1) preferably satisfies Formula (III) below, more preferably satisfies Formula (III-1) below, particularly preferably satisfies Formula (III-2) below.

0.50≤(α+β)/(m−x)≤1.00 Formula (III)

0.60≤(α+β)/(m−x)≤1.00 Formula (III-1)

0.70≤(α+β)/(m−x)≤1.00 Formula (III-2)

In the red fluorescent substance, when emission intensity of a maximum emission wavelength at an excitation wavelength of 450 nm in PLE (Photoluminescence Excitation) spectrum is 1, emission intensity at 720 nm is preferably 0.2 or more.

Preferably, when the emission intensity of the maximum emission wavelength at the excitation wavelength of 450 nm in the PLE (Photoluminescence Excitation) spectrum is 1, the emission intensity at 750 nm is 0.1 or more.

The emission intensity can be confirmed by exciting the red fluorescent substance at a wavelength of 450 nm and measuring emission spectra of wavelengths of from 460 nm to 780 nm with, for example, a spectrophotometer.

The red fluorescent substance has a maximum emission wavelength in the red wavelength band. The maximum emission wavelength is, for example, from 640 nm to 680 nm.

A ratio of the number of nitrogen (N) atoms [12+y−2(n−m)/3] in the Compositional Formula (1) is calculated so that the sum of the ratios of numbers of the respective elements in the Compositional Formula (1) is neutral. That is, when the ratio of the number of nitrogen (N) atoms in the Compositional Formula (1) is δ and the electric charge of each element constituting the Compositional Formula (1) is compensated, the following formula: 2(m−x)+2x+4×9+3y−2n−3δ=0 is satisfied. Therefore, the ratio of the number of nitrogen (N) atoms is calculated as δ=12+y−2(n−m)/3.

The red fluorescent substance of the Compositional Formula (1) described above is a compound constituted by a crystalline structure belonging to the orthorhombic space point group Pmn21. Such a crystal structure is a configuration in which some of silicon (Si) are replaced with aluminum (Al).

The red fluorescent substance represented by the Compositional Formula (1) may include carbon (C). This carbon (C) is an element derived from raw materials in the production process of the red fluorescent substance, and may remain as it is in the synthesized material constituting the red fluorescent substance without being removed during the synthesis process. The inclusion of carbon (C) removes the excess oxygen (O) in the formation process and serves to adjust the amount of oxygen.

### (Method for Producing Red Fluorescent Substance)

A method of the present invention for producing the red fluorescent substance includes at least a baking step and a pulverizing step, and further includes other steps if necessary.

The method of the present invention for producing the red fluorescent substance is a method for producing the red fluorescent substance of the present invention.

### <Baking and Pulverizing Step>

In the baking and pulverizing step, baking a mixture and pulverizing a baked product obtained through the baking are performed.

The mixture is a mixture obtained by mixing a compound of element A, a europium compound that is europium nitride, europium oxide, or both thereof, silicon nitride, aluminum nitride, and melamine so that the element A, europium (Eu), silicon (Si), aluminum (Al), oxygen (O), and nitrogen (N) have ratios of numbers of atoms in the Compositional Formula (1).

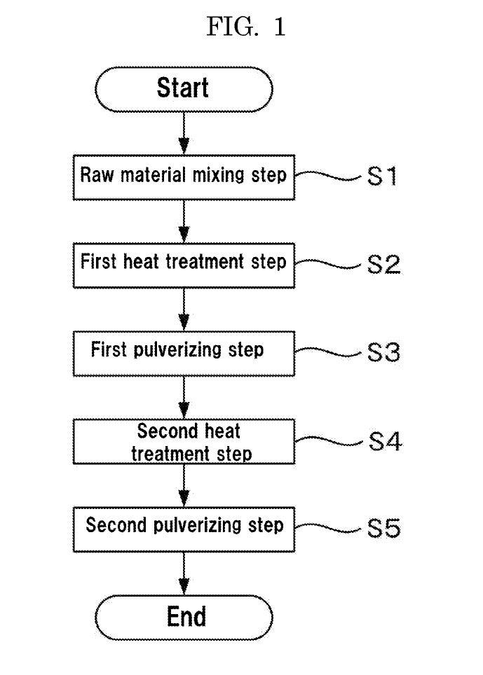

One embodiment of the method for producing the red fluorescent substance will be described below with reference to a flow chart of FIG. 1.

### <Raw Material Mixing Step (S1)>

As presented in FIG. 1, first, “raw material mixing step” S1 is performed. In this raw material mixing step, it is characteristic in that melamine (C₃H₆N₆) is used as a raw material and is mixed together with the raw material compounds containing the elements constituting the Compositional Formula (1).

As the raw material compounds containing the elements constituting the Compositional Formula (1), for example, a compound of the element A, a europium compound, silicon nitride (Si₃N₄), and aluminum nitride (AlN) are provided. Each compound is then weighed to a predetermined molar ratio so that the elements of the Compositional Formula (1) contained in the respective raw material compounds prepared have ratios of numbers of atoms of the Compositional Formula (1). The respective weighed compounds are mixed to form a mixture.

Examples of the compound of the element A include carbonate compounds of the element A, oxides of the element A, and hydroxides of the element A. More specific examples thereof include magnesium carbonate (MgCO₃), calcium carbonate (CaCO₃), calcium oxide (CaO), strontium carbonate (SrCO₃), barium carbonate (BaCO₃), barium oxide (BaO), and barium hydroxide (Ba(OH)₂). These may be used alone or in combination.

Melamine is also added thereto as a flux at a predetermined ratio relative to the sum of numbers of total moles of the compound of the element A, the europium compound, the silicon nitride, and the aluminum nitride (AlN).

The mixture is obtained, for example, through mixing in an agate mortar in a glow box in a nitrogen atmosphere.

### <First Heat Treatment Step (S2)>

Next, “first heat treatment step” S2 is performed. In this first heat treatment step, the mixture is baked to produce a first baked product which is a precursor of the red fluorescent substance. For example, the mixture is charged into a crucible made of boron nitride and is subjected to a heat treatment in a hydrogen (H₂) atmosphere or in a nitrogen (N₂) hydrogen (H₂) mixing atmosphere. In this first heat treatment step, for example, the heat treatment temperature is set to 1400° C. and the heat treatment is performed for 2 hours. The heat treatment temperature and the heat treatment time can be appropriately changed within such a range that the mixture can be baked.

In the first heat treatment step, melamine having a melting point of 250° C. or less is thermally decomposed. The thermally decomposed carbon (C) and hydrogen (H) are combined with some of oxygen (O) contained in the compound of the element A to thereby form carbonic acid gas (CO or CO₂) and H₂O. The carbonic acid gas or H₂O is vaporized and thus is removed from the first baked product. The nitrogen (N) contained in the decomposed melamine also promotes reduction and nitriding.

### <First Pulverizing Step (S3)>

Next, “first pulverizing step” S3 is performed. In the first pulverizing step, the first baked product is pulverized to form first powders. For example, in a glow box in a nitrogen atmosphere, the first baked product is pulverized using an agate mortar and then is passed through, for example, a #100 mesh (opening is about 200 μm) to obtain the first baked product (first powders) having a particle diameter of 3 μm or less as an average particle diameter. This hardly causes ununiformity of components in a second baked product to be produced in the second heat treatment of the next step.

<Second Heat Treatment Step (S4)>

Next, “second heat treatment step” S4 is performed. In this second heat treatment step, the first powders are thermally treated to form a second baked product. For example, the first powders are charged into a crucible made of boron nitride and are subjected to a heat treatment in a nitrogen (N₂) atmosphere or in a nitrogen (N₂) hydrogen (H₂) mixing atmosphere. In this second heat treatment step, the nitrogen atmosphere is pressurized to, for example, 0.85 MPa, or the nitrogen atmosphere is a normal pressure. The heat treatment temperature is set to 1800° C. and the heat treatment is performed for 2 hours. The heat treatment temperature and the heat treatment time can be appropriately changed within such a range that the first powders can be baked.

By performing the second heat treatment step, the red fluorescent substance represented by Compositional Formula (1) can be obtained. The second baked product (red fluorescent substance) obtained through this second heat treatment step is a homogeneous product represented by Compositional Formula (1).

<Second Pulverizing Step (S5)>

Next, “second pulverizing step” S5 is performed. In this second pulverizing step, the second baked product is pulverized to form second powders. For example, in a glow box in a nitrogen atmosphere, the second baked product is pulverized using an agate mortar until an average particle diameter of the second baked product reaches about 3.5 μm, using, for example, a #420 mesh (opening is about 26 μm).

The method for producing the red fluorescent substance makes it possible to obtain the red fluorescent substance of fine powders (e.g., an average particle diameter thereof is about 3.5 μm). As described above, formation of the red fluorescent substance into powders allows homogeneous kneading, when the powders are kneaded into, for example, a transparent resin together with powders of a green fluorescent substance.

As described above, it is possible to obtain the red fluorescent substance of the Compositional Formula (1) containing the respective elements mixed at ratios of numbers of atoms in the “raw material mixing step” S1.

### (White Light Source)

The white light source of the present invention includes at least a blue light emitting diode and a kneaded product, and further includes other components if necessary.

The blue light emitting diode is formed on, for example, an element substrate.

The kneaded product is disposed on, for example, the blue light emitting diode.

The kneaded product is a kneaded product obtained by kneading a red fluorescent substance and a green fluorescent substance in a transparent resin.

The red fluorescent substance is the red fluorescent substance of the present invention.

The green fluorescent substance is not particularly limited and may be appropriately selected depending on the intended purpose. Examples thereof include sulfide-based fluorescent substances.

The sulfide-based fluorescent substance is, for example, a green sulfide fluorescent substance (thiogalate (SGS) fluorescent substance (SrₓM_{1-x-y})Ga₂S₄:Eu_{y}(where M is Ca, Mg, or Ba, and 0≤x<1 and 0<y<0.2 are satisfied), which has a green fluorescence peak of a wavelength of from 530 nm to 550 nm upon illumination of blue excitation light.

As the sulfide-based fluorescent substance, the sulfide-based fluorescent substance represented by any of the following General Formulas (11) to (13) is suitably used.

Sr₁₋ₓGa₂S₄:Euₓ General Formula (11)

(Sr_{1-y}Ca_{y})₁₋ₓGa₂S₄:Euₓ General Formula (12)

(Ba_{z}Sr_{1-z})₁₋ₓGa₂S₄:Euₓ General Formula (13)

In the General Formula (11) to the General Formula (13), x satisfies 0<x<1, y satisfies 0<y<1, and z satisfies 0<z<1.

x preferably satisfies 0.03≤x≤0.20, more preferably satisfies 0.05≤x≤0.18.

y preferably satisfies 0.0055≤y≤0.45, more preferably satisfies 0.05≤y≤0.20.

z preferably satisfies 0.005≤z≤0.45, more preferably satisfies 0.20≤z≤0.40.

The transparent resin is not particularly limited and may be appropriately selected depending on the intended purpose. Examples thereof include silicone resins and epoxy resins.

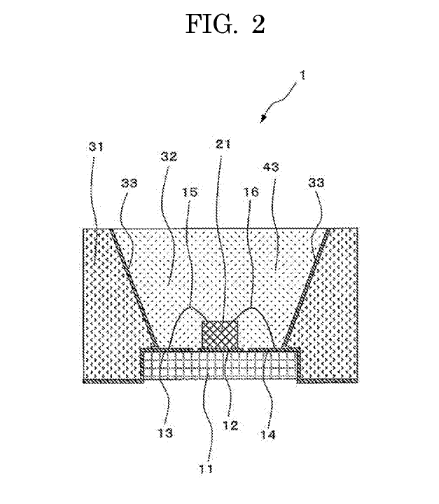

One embodiment of the white light source of the present invention will be described with reference to a schematic cross-sectional view of FIG. 2.

As presented in FIG. 2, a white light source 1 includes a blue light emitting diode 21 on a pad part 12 formed on an element substrate 11. On the element substrate 11, electrodes 13 and 14, which are configured to supply electric power to drive the blue light emitting diode 21, are formed with the insulating property thereof being maintained. Each of the electrodes 13 and 14 is connected to the blue light emitting diode 21 by, for example, lead wires 15 and 16.

For example, a resin layer 31 is provided in the circumference of the blue light emitting diode 21. The resin layer 31 is provided with an opening part 32 that opens over the blue light emitting diode 21. The opening part 32 is formed on inclined surfaces having a wide opening area in the emission direction of the blue light emitting diode 21, and reflection films 33 are formed on the inclined surfaces. That is, in the resin layer 31 having the mortar-like opening part 32, the wall surfaces of the opening part 32 are covered with the reflection films 33 and the blue light emitting diode 21 is disposed at a bottom of the opening part 32. A kneaded product 43 obtained by kneading a red fluorescent substance and a green fluorescent substance in a transparent resin is embedded in the opening part 32, with the kneaded product 43 covering the blue light emitting diode 21, to thereby form the white light source 1.

The red fluorescent substance of the present invention also produces a maximum emission wavelength in the red wavelength band (e.g., a wavelength band of from 640 nm to 680 nm) and has a large emission intensity of a long wavelength of 700 nm or more. Therefore, the three primary colors including blue light from the blue LED light, green light from the green fluorescent substance, and red light from the red fluorescent substance can be used to thereby obtain white light having a broad color gamut. The red fluorescent substance of the present invention is hardly deteriorated even in long-term use.

Therefore, the white light source 1 has an advantage that bright white light having a broad color gamut can be stably obtained for a long period of time.

### (Lighting Device)

The lighting device of the present invention includes at least a lighting substrate and a plurality of white light sources, and further includes other components if necessary.

In the lighting device, for example, a plurality of the white light sources are disposed on the lighting substrate.

The white light source is the white light source of the present invention.

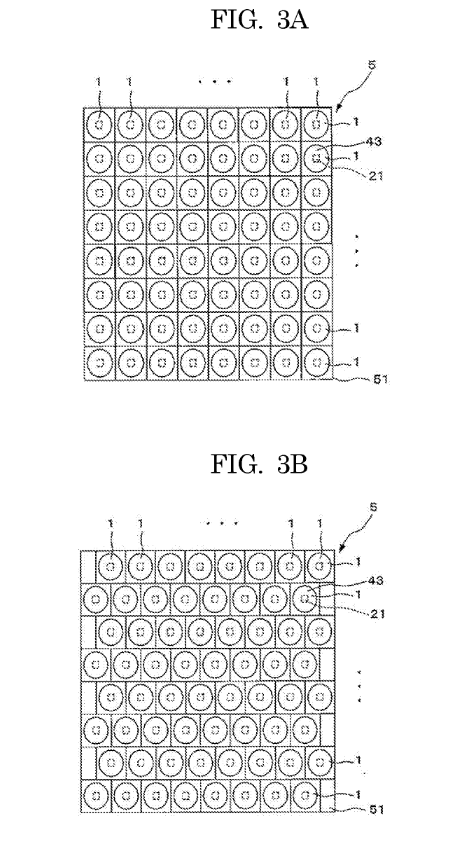

One embodiment of the lighting device of the present invention will be described with reference to schematic planar views of FIGS. 3A and 3B.

As presented in FIGS. 3A and 3B, a lighting device 5 includes a lighting substrate 51 and a plurality of white light sources 1, as described with reference to FIG. 2, disposed on the lighting substrate 51.

Its arrangement example may be, for example, (1) a square lattice arrangement, as presented in FIG. 3A. Alternatively, as presented in FIG. 3B, the arrangement example may be (2) such an arrangement that each white light source 1 is offset by, for example, ½ pitch every other line. The pitch to be offset may be ⅓ pitch, ¼ pitch, in addition to the ½ pitch. Furthermore, it may be offset every one line or every a plurality of lines (e.g., two lines). That is, the way of offsetting the white light source 1 is not limited.

The white light source 1 has the same configuration as that described with reference to FIG. 2. That is, the white light source 1 has, for example, the kneaded product 43 on the blue light emitting diode 21, where the kneaded product 43 is obtained by kneading a red fluorescent substance and a green fluorescent substance in a transparent resin.

Also, the lighting device 5 can be used as, for example, a backlight of a liquid crystal display device. The reason for this is because a plurality of the white light sources 1, which are substantially similar to the point emission, are disposed longitudinally and transversely on the lighting substrate 51, such that it is equivalent to the surface emission. It can also be used in lighting devices for various applications, such as conventional lighting devices, photographic lighting devices, and lighting devices for construction sites.

The lighting device 5 uses the white light source of the present invention, and therefore it is possible to stably obtain bright white light having a broad color gamut for a long period of time. For example, when it is used in the backlight of a liquid crystal display device, it is possible to obtain pure white color having a high brightness on the display screen for a long period of time, which is advantageous in that the quality of the display screen is improved.

### (Liquid Crystal Display Device)

The liquid crystal display device of the present invention includes at least a liquid crystal display panel and a backlight, and further includes other components if necessary.

The backlight includes a plurality of white light sources.

The white light source is configured to light the liquid crystal display panel.

The white light source is the white light source of the present invention.

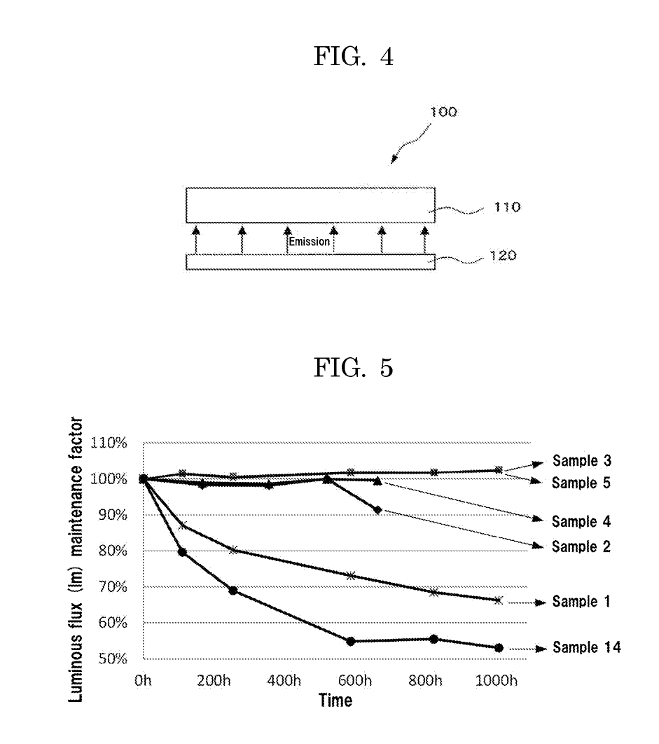

One embodiment of the liquid crystal display device of the present invention will be described with reference to a schematic configuration diagram of FIG. 4.

As presented in FIG. 4, a liquid crystal display device 100 includes a liquid crystal display panel 110 having a transmission display part and a backlight 120 provided with the liquid crystal display panel 110 on a side of the back surface (surface opposite to the display side). In the backlight 120, the lighting device 5, which is described with reference to FIG. 3A or 3B, is used.

In the liquid crystal display device 100, the lighting device of the present invention is used for the backlight 120. Therefore, it is possible to light the liquid crystal display panel 110 with bright white light having a broad color gamut by using the three primary colors of light. Therefore, it is possible to stably obtain pure white color having a high brightness for a long period of time on the display screen of the liquid crystal display panel 110, the color reproducibility is good, and improvement in the quality of the display screen can be achieved, which is advantageous.

### EXAMPLES

The present invention will be described in detail by way of Examples. However, the present invention should not be construed as being limited to these Examples.

### Examples 1 to 11 and Comparative Examples 1 to 3

The red fluorescent substances were synthesized as described below, according to the procedure described using the flow chart of FIG. 1.

First, the “raw material mixing step” S1 was performed. Here, the carbonate compounds of the element A [calcium carbonate (CaCO₃), strontium carbonate (SrCO₃), and barium carbonate (BaCO₃)], europium oxide (Eu₂O₃), silicon nitride (Si₃N₄), aluminum nitride (AlN), and melamine (C₃H₆N₆) were provided. Each of the provided raw material compounds was weighed to a molar ratio presented in Table 1 below and was mixed in an agate mortar in a glow box in a nitrogen atmosphere to thereby obtain a mixture. A molar ratio of melamine is a ratio thereof relative to the sum of numbers of total moles of the other compounds.

TABLE 1

| | Sam- | | | | | | | | Compositional | | | |
|---|---|---|---|---|---|---|---|---|---|---|---|---|
| | ple | CaCO₃ | SrCO₃ | BaCO₃ | Eu₂O₃ | Si₃N₄ | AlN | Melamine | Formula (1) | | | |
| | No. | [mol %] | [mol %] | [mol %] | [mol %] | [mol %] | [mol %] | [mol %] | m | x | y | n |
| Comp. | 1 | 15.8 | 36.8 | 0.0 | 1.0 | 45.0 | 1.4 | 50 | 3.64 | 0.13 | 0.09 | 1 |
| Ex. 1 | | | | | | | | | | | | |
| Ex. 1 | 2 | 12.8 | 20.5 | 17.9 | 1.9 | 45.5 | 1.4 | 50 | 3.64 | 0.25 | 0.09 | 1 |
| Ex. 2 | 3 | 7.7 | 14.8 | 28.7 | 1.9 | 45.5 | 1.4 | 30 | 3.64 | 0.25 | 0.09 | 1 |
| Ex. 3 | 4 | 7.7 | 25.6 | 17.9 | 1.9 | 45.5 | 1.4 | 50 | 3.64 | 0.25 | 0.09 | 1 |
| Ex. 4 | 5 | 5.1 | 17.4 | 28.7 | 1.9 | 45.5 | 1.4 | 30 | 3.64 | 0.25 | 0.09 | 1 |
| Ex. 5 | 6 | 5.1 | 14.3 | 31.8 | 1.9 | 45.5 | 1.4 | 50 | 3.64 | 0.25 | 0.09 | 1 |
| Ex. 6 | 7 | 5.1 | 10.2 | 35.9 | 1.9 | 45.5 | 1.4 | 50 | 3.64 | 0.25 | 0.09 | 1 |
| Ex. 7 | 8 | 5.1 | 5.1 | 41.0 | 1.9 | 45.5 | 1.4 | 30 | 3.64 | 0.25 | 0.09 | 1 |
| Ex. 8 | 9 | 5.1 | 5.1 | 41.0 | 1.9 | 45.5 | 1.4 | 50 | 3.64 | 0.25 | 0.09 | 1 |
| Ex. 9 | 10 | 5.1 | 5.1 | 41.0 | 1.9 | 45.5 | 1.4 | 70 | 3.64 | 0.25 | 0.09 | 1 |
| Ex. 10 | 11 | 5.1 | 0 | 46.1 | 1.9 | 45.5 | 1.4 | 50 | 3.64 | 0.25 | 0.09 | 1 |
| Ex. 11 | 12 | 5.1 | 0 | 46.1 | 1.9 | 45.5 | 1.4 | 70 | 3.64 | 0.25 | 0.09 | 1 |
| Comp. | 13 | 1.5 | 6.1 | 43.6 | 1.9 | 45.5 | 1.4 | 50 | 3.64 | 0.25 | 0.09 | 1 |
| Ex. 2 | | | | | | | | | | | | |
| Comp. | 14 | 0 | 52.6 | 0 | 1.0 | 45.0 | 1.4 | 50 | 3.64 | 0.13 | 0.09 | 1 |
| Ex. 3 | | | | | | | | | | | | |

The ratios of the respective elements (Ca, Sr, and Ba) relative to the element A (Ca ratio=Ca/A, Sr ratio=Sr/A, and Ba ratio=Ba/A), α/(α+β), β/(α+β), and (α+β)/(m−x) are presented in Table 2 below.

TABLE 2

| | Sam- | | | | | | |
|---|---|---|---|---|---|---|---|
| | ple | Ca/A | Sr/A | Ba/A | α/ | β/ | (α + β)/ |
| | No. | [mol %] | [mol %] | [mol %] | (α + β) | (α + β) | (m − x) |
| Comp. | 1 | 30 | 70 | 0 | 1.00 | 0.00 | 0.30 |
| Ex. 1 | | | | | | | |
| Ex. 1 | 2 | 25 | 40 | 35 | 0.42 | 0.58 | 0.60 |
| Ex. 2 | 3 | 15 | 29 | 56 | 0.21 | 0.79 | 0.71 |
| Ex. 3 | 4 | 15 | 50 | 35 | 0.30 | 0.70 | 0.50 |
| Ex. 4 | 5 | 10 | 34 | 56 | 0.15 | 0.85 | 0.66 |
| Ex. 5 | 6 | 10 | 28 | 62 | 0.14 | 0.86 | 0.72 |
| Ex. 6 | 7 | 10 | 20 | 70 | 0.13 | 0.88 | 0.80 |
| Ex. 7 | 8 | 10 | 10 | 80 | 0.11 | 0.89 | 0.90 |
| Ex. 8 | 9 | 10 | 10 | 80 | 0.11 | 0.89 | 0.90 |
| Ex. 9 | 10 | 10 | 10 | 80 | 0.11 | 0.89 | 0.90 |
| Ex. 10 | 11 | 10 | 0 | 90 | 0.10 | 0.90 | 1.00 |
| Ex. 11 | 12 | 10 | 0 | 90 | 0.10 | 0.90 | 1.00 |
| Comp. | 13 | 3 | 12 | 85 | 0.03 | 0.97 | 0.88 |
| Ex. 2 | | | | | | | |
| Comp. | 14 | 0 | 100 | 0 | — | — | 0.00 |
| Ex. 3 | | | | | | | |

Next, the “first heat treatment step” S2 was performed. Here, the above mixture was charged into a crucible formed of boron nitride and was subjected to a heat treatment at 1500° C. for 2 hours in a nitrogen (N₂) hydrogen (H₂) mixing atmosphere.

Next, the “first pulverizing step” S3 was performed. Here, in a glow box in a nitrogen atmosphere, the above first baked product was pulverized using an agate mortar and was then passed through a #100 mesh (opening was about 200 μm) to obtain a first baked product having a particle diameter of 3 μm or less as an average particle diameter.

Next, the “second heat treatment step” S4 was performed. Here, the powders of the first baked product were charged into a crucible made of boron nitride and were subjected to a heat treatment at 1700° C. for 2 hours in a nitrogen (N₂) hydrogen (H₂) mixing atmosphere of normal pressure. As a result, a second baked product was obtained.

Next, the “second pulverizing step” S5 was performed. Here, in a glow box in a nitrogen atmosphere, the second baked product was pulverized using an agate mortar. A #420 mesh (opening was about 26 μm) was used for pulverization until an average particle diameter thereof reached about 3.5 μm.

Through the method for producing the red fluorescent substance as described above, the red fluorescent substance of fine powders (average particle diameter thereof was about 3.5 μm) was obtained.

The red fluorescent substances produced as described above were analyzed through the ICP. As a result, it was confirmed that the elements which constitute the Compositional Formula (1) contained in the raw material compounds were contained in the red fluorescent substance at almost the same molar ratios (ratios of numbers of atoms) as presented in the Compositional Formula (1).

### <Measurement of Emission Intensity>

The emission spectrum was measured for each red fluorescent substance obtained as above. It was excited at a wavelength of 450 nm and the measurement was performed using a spectrophotometer (FP-6500, available from JASCO Corporation) at a wavelength of from 460 nm to 780 nm. Results are presented in Table 3 below.

TABLE 3

| | | | 750 nm | 780 nm |
|---|---|---|---|---|
| | Sample | λp | Emission | Emission |
| | No. | [nm] | intensity | intensity |
| Comp. | 1 | 651 | 0.265 | 0.132 |
| Ex.1 | | | | |
| Ex.1 | 2 | 649 | 0.304 | 0.112 |
| Ex.2 | 3 | 649 | 0.247 | 0.119 |
| Ex.3 | 4 | 658 | 0.251 | 0.144 |
| Ex.4 | 5 | 648 | 0.239 | 0.112 |
| Ex.5 | 6 | 651 | 0.252 | 0.116 |
| Ex.6 | 7 | 648 | 0.244 | 0.117 |
| Ex.7 | 8 | 654 | 0.264 | 0.132 |
| Ex.8 | 9 | 651 | 0.240 | 0.103 |
| Ex.9 | 10 | 657 | 0.276 | 0.135 |
| Ex.10 | 11 | 651 | 0.251 | 0.112 |
| Ex.11 | 12 | 658 | 0.288 | 0.135 |
| Comp. | 13 | 644 | 0.188 | 0.083 |
| Ex.2 | | | | |
| Comp. | 14 | 630 | 0.112 | 0.040 |
| Ex.3 | | | | |

In Table 3, λp represents the maximum emission wavelength. The emission intensities at 750 nm and 780 nm are each a relative value, when the emission intensity at the maximum emission wavelength (λp) is defined as 1.

The red fluorescent substances of Examples 1 to 11 were excellent in the emission property, because they had the emission intensity of 0.2 or more at 750 nm, the emission intensity of 0.1 or more at 780 nm, and a large emission intensity in a long wavelength region of from 700 nm to infrared.

On the other hand, the red fluorescent substances of Comparative Examples 2 and 3 were not sufficient in the emission property, because they had the emission intensity of less than 0.2 at 750 nm and the emission intensity of less than 0.1 at 780 nm.

### <LED Lighting Test>

The red fluorescent substance was dispersed in a resin (methyl-based KER-2910) in the LED package. The resin was then cured to obtain an LED package containing the red fluorescent substance. The lighting test was performed on this LED package.

As the test conditions, electricity was continuously supplied to the LED at 120 mA under a 60° C. 90% RH environment, and the initial luminous flux maintenance factor (lm %) at this time was confirmed.

Details of the measurement are as follows. Specifically, spectrum of the spectral radiant flux (intensity: W/nm) was measured with an integrating sphere using a light measuring device (available from Labsphere, system-type name: “CSLMS LED-1061”, model: 10 inches (Φ25)/LMS-100) to measure the total luminous flux (lumen: lm). After the data before the accelerated environmental testing of the above parameters were obtained, sample data after the accelerated environmental testing over a certain period of time were similarly measured. Then, the lm variation rate (%) from the initial value (luminous flux maintenance factor) was calculated based on the following calculation formula.

lm variation rate (%): (lm after the testing/initial lm)×100

The test results were evaluated based on the following evaluation criteria. Results are presented in Table 4.

### [Evaluation Criteria]

A: At a continuous lighting time of 660 hours, the luminous flux maintenance factor is 95% or more.

B: At a continuous lighting time of 660 hours, the luminous flux maintenance factor is 90% or more but less than 95%.

C: At a continuous lighting time of 660 hours, the luminous flux maintenance factor is 60% or more but less than 90%.

D: At a continuous lighting time of 660 hours, the luminous flux maintenance factor is less than 60%.

Results of samples 1 to 5 and 14 are presented in FIG. 5. The graphs of samples 3 and 5 are overlapped.

The samples 6 to 13 are the result obtained by continuously supplying electricity to the LEDs at 240 mA to 350 mA under a 60° C. 90% RH environment.

TABLE 4

| | | Luminous flux | |
|---|---|---|---|
| | | maintenance factor | |
| | Sample | | Evaluation |
| | No. | [%] | result |
| Comp. | 1 | 72% | C |
| Ex.1 | | | |
| Ex.1 | 2 | 91% | B |
| Ex.2 | 3 | 102% | A |
| Ex.3 | 4 | 100% | A |
| Ex.4 | 5 | 102% | A |
| Ex.5 | 6 | 100% | A |
| Ex.6 | 7 | 100% | A |
| Ex.7 | 8 | 100% | A |
| Ex.8 | 9 | 100% | A |
| Ex.9 | 10 | 100% | A |
| Ex.10 | 11 | 100% | A |
| Ex.11 | 12 | 100% | A |
| Comp. | 13 | 100% | A |
| Ex.2 | | | |
| Comp. | 14 | 55% | D |
| Ex.3 | | | |

It was confirmed that the red fluorescent substances of Examples 1 to 11 had a high luminous flux maintenance factor (i.e., deterioration hardly occurs) at a continuous lighting time of 660 hours. In particular, the red fluorescent substances of Examples 2 to 11 had a considerably excellent luminous flux maintenance factor of 95% or more at a continuous lighting time of 660 hours, confirming that almost no deterioration of the red fluorescent substances occurred even through the continuous lighting of the LED.

On the other hand, it was confirmed that the red fluorescent substances of Comparative Examples 1 and 3 presented a low luminous flux maintenance factor, and the red fluorescent substances were deteriorated even through the continuous lighting of the LED.

### INDUSTRIAL APPLICABILITY

The red fluorescent substance of the present invention can be suitably used as a white light source using a blue LED because it has a large emission intensity of a long wavelength of 700 nm or more and deterioration hardly occurs even in long-term use.

What is claimed is:

1. A red fluorescent substance comprising:
element A, europium (Eu), silicon (Si), aluminum (Al), oxygen (O), and nitrogen (N) at ratios of numbers of atoms in Compositional Formula (1) below:
[A₍ₘ₋ₓ₎Euₓ]Si₉Al_{y}OₙN_{[12+y-2(n-m)/3]} Compositional Formula (1)
where in the Compositional Formula (1), the element A is a Group 2 element including calcium (Ca) and barium (Ba), m, x, y, and n in the Compositional Formula (1) satisfy 3<m<5, 0<x<1, 0.012≤y≤0.10, and 0<n<10, respectively and when a ratio of the number of Ca atoms is α and a ratio of the number of Ba atoms is β, the Compositional Formula (I) satisfies Formula (I) below:
0.05≤α/(α+β)<1.00 Formula (I).

2. The red fluorescent substance according to claim 1,
wherein the Compositional Formula (1) further satisfies Formula (II) below:
0.30≤β/(α+β)<1.00 Formula (II).

3. The red fluorescent substance according to claim 1,
wherein the Compositional Formula (1) further satisfies Formula (III) below:
0.50≤(α+β)/(m−x)≤1.00 Formula (III).

4. The red fluorescent substance according to claim 1,
wherein when emission intensity of a maximum emission wavelength at an excitation wavelength of 450 nm in PLE (Photoluminescence Excitation) spectrum is 1, emission intensity at 720 nm is 0.2 or more.

5. The red fluorescent substance according to claim 1,
wherein when emission intensity of a maximum emission wavelength at an excitation wavelength of 450 nm in PLE (Photoluminescence Excitation) spectrum is 1, emission intensity at 750 nm is 0.1 or more.

6. A method for producing the red fluorescent substance according to claim 1, the method comprising:
mixing a compound of element A, a europium compound that is europium nitride, europium oxide, or both thereof, silicon nitride, aluminum nitride, and melamine to form a mixture so that the element A, europium (Eu), silicon (Si), aluminum (Al), oxygen (O), and nitrogen (N) have ratios of numbers of atoms in the Compositional Formula (1), and baking the mixture; and pulverizing a baked product obtained through the baking.

7. The method for producing the red fluorescent substance according to claim 6,
wherein the baking the mixture and the pulverizing the baked product obtained through the baking are repeatedly performed.

8. A white light source comprising:
a blue light emitting diode formed on an element substrate; and
a kneaded product that is disposed on the blue light emitting diode and is obtained by kneading a red fluorescent substance and a green fluorescent substance in a transparent resin,
wherein the red fluorescent substance is the red fluorescent substance according to claim 1.

9. A lighting device comprising:
a lighting substrate; and
a plurality of white light sources disposed on the lighting substrate,
wherein each of the plurality of white light sources is the white light source according to claim 8.

10. A liquid crystal display device comprising:
a liquid crystal panel; and
a backlight using a plurality of white light sources configured to light the liquid crystal panel,
wherein each of the plurality of white light sources is the white light source according to claim 8.
